(19) United States
(12) Patent Application Publication
(10) Pub. No.: US 2020/0240716 A1
(43) Pub. Date: Jul. 30, 2020

(54) HEAT DISSIPATION DEVICE AND LIGHT IRRADIATION DEVICE HAVING SAME

(71) Applicant: HOYA CANDEO OPTRONICS CORPORATION, Toda-shi (JP)

(72) Inventor: Hiroaki WATANABE, Toda-shi (JP)

(73) Assignee: HOYA CANDEO OPTRONICS CORPORATION, Toda-shi (JP)

(21) Appl. No.: 16/752,540

(22) Filed: Jan. 24, 2020

(30) Foreign Application Priority Data
Jan. 27, 2019 (JP) 2019-011755

(51) Int. Cl. F28D 15/02; H01L 25/075; H05K 7/20; G21K 5/00

(52) U.S. Cl. CPC F28D 15/0275; G21K 5/00; H05K 7/20336; H01L 25/0753

(57) ABSTRACT

Provided is a heat dissipation device capable of uniformly cooling an entire base plate (support member) without generating stress in a heat pipe. A heat dissipation device configured to dissipate heat of a heat source into the air, the heat dissipation device including: a support member disposed such that a side of a first principal surface is in close contact with a heat source; a heat pipe thermally joined to a second principal surface of the support member and configured to transport the heat from the heat source; and multiple heat radiation fins disposed in a space adjoining the second principal surface, thermally joined to the heat pipe, and configured to dissipate the heat transported by the heat pipe, in which the respective heat radiation fins are directly joined to the second principal surface in a region other than a region in which the heat pipe is mounted.

### TECHNICAL FIELD

The present disclosure relates to a heat dissipation device configured to cool a light source and the like of a light irradiation device, and more particularly, to a heat pipe type heat dissipation device having a heat pipe penetratively inserted into multiple heat radiation fins, and a light irradiation device having the heat dissipation device.

### BACKGROUND ART

In the related art, ultraviolet curable ink, which is cured by being irradiated with ultraviolet rays, is used as ink for sheet-fed offset printing. In addition, ultraviolet curable resin is used as an adhesive around a flat panel display (FPD) such as a liquid crystal panel or an organic EL (electro luminescence) panel. In general, an ultraviolet ray irradiation device configured to emit ultraviolet rays is used to cure the ultraviolet curable ink or the ultraviolet curable resin.

As the ultraviolet ray irradiation device, there has been known in the related art a lamp type irradiation device that uses a high-pressure mercury lamp, a mercury xenon lamp, or the like as a light source. However, recently, there has been developed an ultraviolet ray irradiation device that uses a light emitting diode (LED) as a light source instead of a discharge lamp in the related art in order to meet the requirement of a reduction in power consumption, a long lifespan, and a compact size of the device.

The ultraviolet ray irradiation device, which uses the LED as a light source, is disclosed in Patent Document 1, for example. The light irradiation device disclosed in Patent Document 1 has an LED unit mounted with multiple LED elements.

Because most of the inputted electric power is converted into heat when the LED elements are used for the light source as described above, there is a problem in that emission efficiency and endurance deteriorate due to heat generated by the LED elements and there is a problem with how to deal with heat. Therefore, the light irradiation device disclosed in Patent Document 1 adopts a configuration at a rear side of the LED unit mounted with the multiple LED elements, and the configuration has a heat pipe and multiple heat radiation fins connected to and fitted with the heat pipe, and transfers heat generated by the LED elements through the heat pipe, thereby dissipating the heat into the air from the heat radiation fins.

### DOCUMENT OF RELATED ART

### Patent Document

[Patent Document 1] Japanese Patent Application Laid-Open No. 2013-77575

### DISCLOSURE

### Technical Problem

In the case of the heat dissipation device of the light irradiation device disclosed in Patent Document 1, the LED elements are efficiently cooled because the heat generated by the LED elements is quickly transferred by the heat pipe and then dissipated from the multiple heat radiation fins. Therefore, it is possible to not only prevent a deterioration in performance of the LED elements or damage to the LED elements, but also emit light with high brightness.

However, in the case of the configuration, like the heat dissipation device of Patent Document 1, in which the heat pipe is folded in a “⊐” shape, because the multiple heat radiation fins are mounted on one straight portion of the heat pipe, the configuration has a so-called cantilevered structure, shear stress is generated in the other straight portion, a curved portion, or the like of the heat pipe, and stress is concentrated on a joint portion between the heat pipe and a support member, which causes a problem with mechanical strength because the heat pipe becomes easily damaged or detached.

The present disclosure has been made in consideration of these circumstances, and an object of the present disclosure is to provide a heat dissipation device capable of uniformly cooling an entire base plate (support member) without generating stress in a heat pipe, and provide a light irradiation device having the heat dissipation device.

### Technical Solution

In order to achieve the above-mentioned object, a heat dissipation device according to the present disclosure is disposed to be in close contact with a heat source and configured to dissipate heat of the heat source into the air, and the heat dissipation device includes: a support member having a plate shape and disposed such that a side of a first principal surface is in close contact with the heat source; a heat pipe thermally joined to a second principal surface opposite to the first principal surface of the support member and configured to transport the heat from the heat source; and multiple heat radiation fins disposed in a space adjoining the second principal surface, thermally joined to the heat pipe, and configured to dissipate the heat transported by the heat pipe, in which the heat pipe has a first straight portion thermally joined to the support member, a second straight portion thermally joined to the multiple heat radiation fins, and a connecting portion connecting one end of the first straight portion and one end of the second straight portion so that the first straight portion and the second straight portion are connected, and in which the respective heat radiation fins are directly joined to the second principal surface in a region other than a region in which the heat pipe is mounted.

According to this configuration, because the respective heat radiation fins are joined not only directly to the second straight portion but also to the second principal surface, it is possible to stably cool the support member without generating stress in the first straight portion or the connecting portion of the heat pipe.

In addition, the support member may be a vapor chamber thermally joined to the heat source. In addition, each of the heat radiation fins may be directly joined to the second principal surface at an edge portion of the second principal surface in a direction approximately orthogonal to a direction in which the first straight portion extends.

In addition, the heat radiation fin may be partially joined to the first straight portion in a region in which the heat pipe is mounted.

In addition, the multiple heat pipes may be provided, and the first straight portions of the respective heat pipes may be disposed at predetermined intervals in a direction approximately orthogonal to a direction in which the first straight portion extends. In addition, in this case, when viewed in the direction in which the first straight portion extends, positions of the second straight portions of the respective heat pipes may be different in a direction approximately perpendicular to the second principal surface and a direction approximately parallel to the second principal surface.

In addition, when the multiple heat dissipation devices are arranged in the direction in which the first straight portion extends, the heat dissipation devices may be connected so that the first principal surfaces are continuous.

In addition, from another point of view, a light irradiation device of the present disclosure may include any one heat dissipation device, a substrate disposed to be in close contact with the first principal surface, and multiple LED elements disposed on a surface of the substrate. In addition, in this case, the LED element may emit light with a wavelength that acts on ultraviolet curable resin.

### Advantageous Effects

According to the present disclosure as described above, the heat dissipation device capable of uniformly cooling the entire base plate (support member) without generating stress in the heat pipe is implemented, and the light irradiation device having the heat dissipation device is implemented.

### DESCRIPTION OF DRAWINGS

FIG. 1A and FIG. 1B are, respectively, an external appearance view for explaining a schematic configuration of a light irradiation device having a heat dissipation device according to an exemplary embodiment of the present disclosure, in which FIG. 1A is a perspective view and FIG. 1B is a front view.

FIG. 2 is a cross-sectional view taken along line B-B in FIG. 1B.

FIG. 3A is a cross-sectional view taken along line A-A in FIG. 1B, and FIG. 3B is an enlarged view of part B in FIG. 3A.

FIG. 4A and FIG. 4B are, respectively, a view illustrating a state in which the light irradiation devices each having the heat dissipation device according to the exemplary embodiment of the present disclosure are connected in an X-axis direction, in which FIG. 4A is a front view and FIG. 4B is a bottom view.

FIG. 5 is a view for explaining coolability of the light irradiation device having the heat dissipation device according to the exemplary embodiment of the present disclosure.

### DESCRIPTION OF MAIN REFERENCE NUMERALS OF DRAWINGS

10: Light irradiation device

11: Light irradiation device (Modified Example)

10X: Light irradiation device (Comparative Example)

10Y: Light irradiation device (Comparative Example)

100: LED unit

105: Substrate

110: LED element

200: Heat dissipation device

201: Vapor chamber

201a: First principal surface

201b: Second principal surface

203: Heat pipe

203a: First straight portion

203b: Second straight portion

203c: Connecting portion

203ca: Curved portion

203cb: Curved portion

205: Heat radiation fin

205X: Heat radiation fin (Comparative Example)

205Y: Heat radiation fin (Comparative Example)

205a: Through hole

205b: Cutout portion

E: Both ends

P: Hollow portion

S: Gap

VC: Effective area

HW: Heat pipe mounting region

LW: LED mounting region

### BEST MODE

Hereinafter, exemplary embodiments of the present disclosure will be described in detail with reference to the drawings. Further, in the drawings, identical or equivalent constituent elements are denoted by the same reference numerals, and descriptions thereof will be omitted.

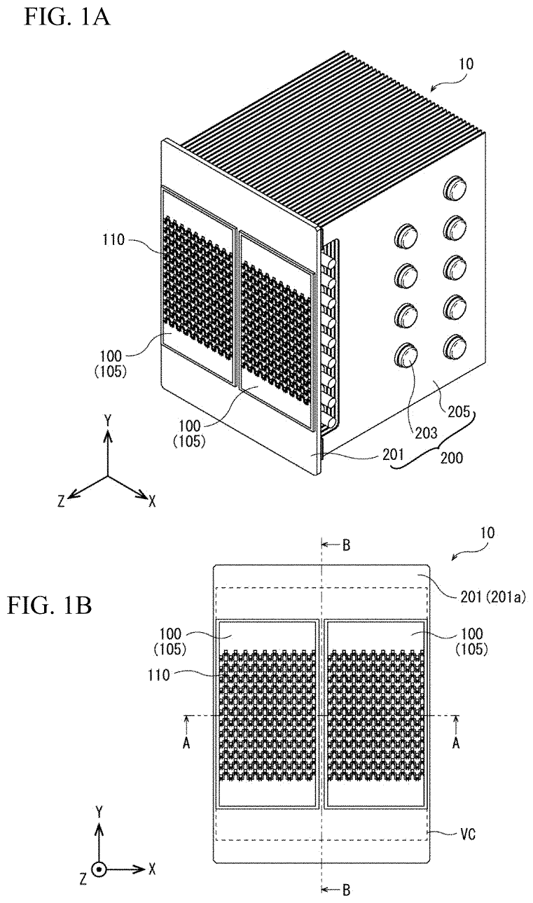

FIG. 1 is an external appearance view for explaining a schematic configuration a light irradiation device 10 having a heat dissipation device 200 according to an exemplary embodiment of the present disclosure, in which FIG. 1A is a perspective view, and FIG. 1B is a front view. The light irradiation device 10 of the present exemplary embodiment is a device mounted in a light source device configured to cure ultraviolet curable ink used as ink for sheet-fed offset printing or ultraviolet curable resin used as an adhesive for a flat panel display (FPD). The light irradiation device 10 is disposed to be directed toward an irradiation object and emits ultraviolet rays to a predetermined area of the irradiation object. In the present specification, a direction in which a first straight portion 203a of a heat pipe 203 of the heat dissipation device 200 extends is defined as an X-axis direction, a direction in which the first straight portions 203a of the heat pipes 203 are arranged is defined as a Y-axis direction, and a direction orthogonal to the X axis and the Y axis is defined as a Z-axis direction. Further, because the required irradiation area varies depending on the purposes or specifications of the light source device in which the light irradiation device 10 is mounted, the light irradiation devices 10 of the present exemplary embodiment are configured to be connectable in the X-axis direction and the Y-axis direction (the details are to be described below).

(Configuration of Light Irradiation Device 10)

As illustrated in FIG. 1, the light irradiation device 10 of the present exemplary embodiment has two LED units 100 and the heat dissipation device 200.

(Configuration of LED Unit 100)

Each of the LED units 100 has a plate shaped substrate 105 having a rectangular shape defined in the X-axis direction and the Y-axis direction, and multiple LED elements 110 disposed on the substrate 105.

The substrate 105 is a rectangular wiring substrate made of a material (e.g., copper, aluminum, or aluminum nitride) having high thermal conductivity. As illustrated in FIG. 1B, 240 LED elements 110 are mounted on a surface of the substrate 105 at predetermined intervals in the X-axis direction and the Y-axis direction in a zigzag shape in a chip on board (COB) manner and in a mode of 10 (X-axis direction)×24 rows (Y-axis direction). An anode pattern (not illustrated) and a cathode pattern (not illustrated) are formed on the substrate 105 to supply electric power to each of the

LED elements 110. Each of the LED elements 110 is electrically connected to the anode pattern and the cathode pattern. In addition, the substrate 105 is electrically connected to an LED drive circuit (not illustrated) by means of a non-illustrated wire cable, and each of the LED elements 110 is configured to be supplied with a drive current from the LED drive circuit through the anode pattern and the cathode pattern.

The LED element 110 is a semiconductor element configured to be supplied with the drive current from the LED drive circuit and emit ultraviolet rays (e.g., a wavelength of 365 nm, 385 nm, 395 nm, or 405 nm). When the drive current is supplied to each of the LED elements 110, the ultraviolet rays are emitted from the LED units 100 with an approximately uniform light amount distribution in the X-axis direction and the Y-axis direction.

(Configuration of Heat Dissipation Device 200)

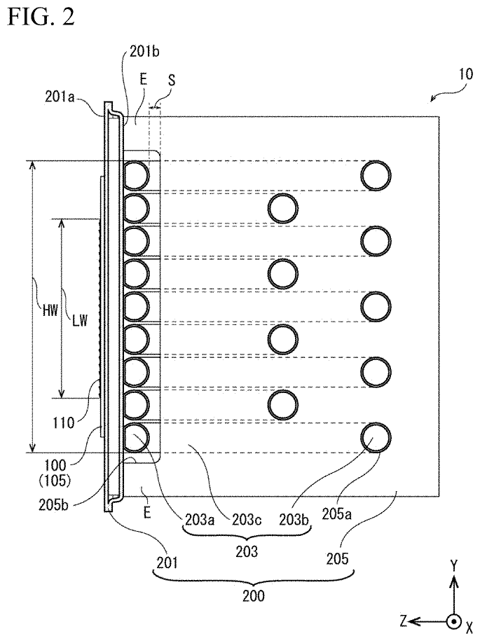

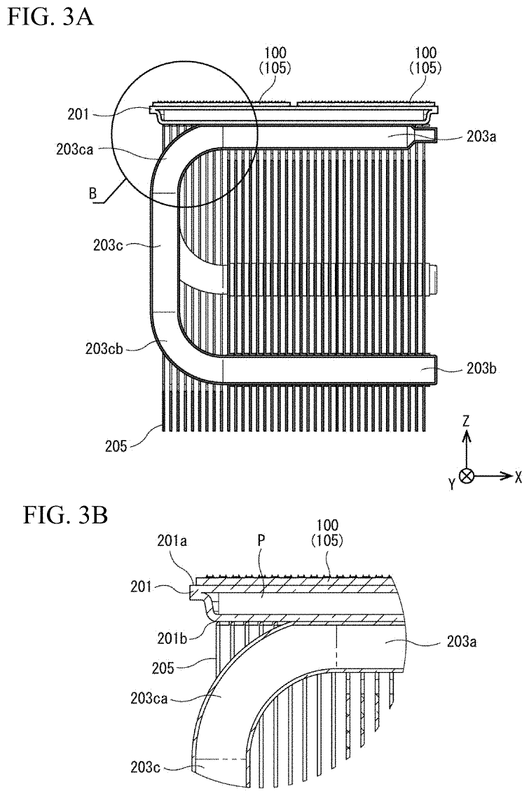

FIG. 2 and FIG. 3 are views for explaining a configuration of the heat dissipation device 200 of the present exemplary embodiment. FIG. 2 is a cross-sectional view taken along line B-B in FIG. 1B, FIG. 3A is a cross-sectional view taken along line A-A in FIG. 1B, and FIG. 3B is an enlarged view of part B in FIG. 3A. The heat dissipation device 200 is a device disposed to be in close contact with a rear surface of the substrate 105 of the LED unit 100 (a surface opposite to a surface on which the LED elements 110 are mounted) and configured to dissipate heat generated by the respective LED elements 110. The heat dissipation device 200 includes a vapor chamber 201, multiple heat pipes 203, and multiple heat radiation fins 205. When the drive current flows to the respective LED elements 110 and the ultraviolet rays are emitted from the respective LED elements 110, a temperature is raised by self-heating of the LED elements 110, which causes a problem of a considerable deterioration in luminous efficiency. Therefore, in the present exemplary embodiment, the heat dissipation device 200 is provided to be in close contact with the rear surface of the substrate 105, and the heat generated by the LED elements 110 is transferred to the heat dissipation device 200 through the substrate 105 and forcibly dissipated.

The vapor chamber 201 is a planar member made of metal (e.g., metal such as copper, aluminum, iron, magnesium, or an alloy including the metal) and having a hollow portion P in which a working fluid (e.g., water, alcohol, ammonia, or the like) is decompressed and encapsulated (FIG. 3B). A first principal surface 201a of the vapor chamber 201 is mounted to be in close contact with the rear surface of the substrate 105 through a heat conduction member such as grease and receives heat generated by the LED unit 100 which is a heat source. The first straight portion 203a of the heat pipe 203 is thermally and mechanically joined, by a non-illustrated fixture, an adhesive, or the like, to a second principal surface 201b (a surface opposite to the first principal surface 201a) of the vapor chamber 201 of the present exemplary embodiment, and the heat pipe 203 is supported by the vapor chamber 201. In this way, the vapor chamber 201 of the present exemplary embodiment supports the heat pipe 203 and serves as a heat receiving portion that receives heat from the LED unit 100. Further, when the vapor chamber 201 receives heat from the LED unit 100, the working fluid in the vapor chamber 201 is vaporized, the vapor moves in the hollow portion P, and the heat transferred to the vapor chamber 201 is transferred to the heat pipe 203 from the surface at the side of the heat pipe 203. Further, when the heat transferred to the vapor chamber 201 is transferred to the heat pipe 203, the vapor of the working fluid returns to a liquid by dissipating the heat. As this action is repeated, the heat from the LED unit 100 is efficiently transferred to the heat pipe 203. Further, in the present exemplary embodiment, when the LED unit 100 is mounted on the vapor chamber 201, the LED elements 110 are positioned at an approximately central portion in the Y-axis direction of an effective area VC of the vapor chamber 201 so that the heat from the LED unit 100 (i.e., from the LED elements 110) is efficiently transferred (FIG. 1B). That is, the heat from the LED elements 110 is transferred to be spread in the Y-axis direction by the vapor chamber 201, such that the heat is transferred from the second principal surface 201b to the first straight portion 203a of the heat pipe 203.

The heat pipe 203 is a hollow sealed pipe having an approximately circular cross section in which the working fluid (e.g., water, alcohol, ammonia, or the like) is decompressed and encapsulated, and the heat pipe 203 is made of metal (e.g., metal such as copper, aluminum, iron, magnesium, or an alloy including the metal). As illustrated in FIG. 3, each of the heat pipes 203 of the present exemplary embodiment has an approximately inverted “⊐” shape when viewed in the Y-axis direction and includes the first straight portion 203a extending in the X-axis direction, a second straight portion 203b extending in the X-axis direction approximately in parallel with the first straight portion 203a, and a connecting portion 203c connecting one end of the first straight portion 203a (one end in a direction opposite to the X-axis direction) and one end of the second straight portion 203b (one end in the direction opposite to the X-axis direction) so that the first straight portion 203a and the second straight portion 203b are continuous. Further, the heat pipe 203 of the present exemplary embodiment is disposed so as not to deviate from a space adjoining the second principal surface 201b of the vapor chamber 201 so that the heat pipes 203 do not interrupt one another when the light irradiation devices 10 are connected.

The first straight portion 203a of each of the heat pipes 203 is a portion that receives heat from the vapor chamber 201 and has a D-shaped cross section in a Y-Z plane. The first straight portion 203a is fixed by a non-illustrated fixture or adhesive in a state in which a flat portion of the first straight portion 203a is in contact with the second principal surface 201b of the vapor chamber 201. The first straight portion 203a is thermally and mechanically joined to the vapor chamber 201 (FIG. 2). In the present exemplary embodiment, the first straight portions 203a of the nine heat pipes 203 are disposed at predetermined intervals in the Y-axis direction or disposed adjacent to one another (FIG. 2). Further, as illustrated in FIG. 2, in the present exemplary embodiment, when viewed in the X-axis direction, a width in the Y-axis direction of a region (hereinafter, referred to as a “heat pipe mounting region HW”) in which the first straight portions 203a of the heat pipes 203 are disposed on the second principal surface 201b of the vapor chamber 201 is greater than a width in the Y-axis direction of a region (hereinafter, referred to as an “LED mounting region LW”) in which the LED elements 110 are disposed, such that the heat from the LED elements 110 is assuredly transferred to the first straight portions 203a of the heat pipes 203.

The second straight portion 203b of each of the heat pipes 203 is a portion that dissipates the heat received by the first straight portion 203a, and the second straight portion 203b of each of the heat pipes 203 is penetratively inserted into through holes 205a of the heat radiation fins 205 and mechanical and thermally joined to the heat radiation fins 205 (FIG. 2). As illustrated in FIG. 2, in the present exemplary embodiment, the second straight portions 203b of the nine heat pipes 203 are disposed at different positions in the Y-axis direction and the Z-axis direction so as not to interfere with one another. Further, a length of the second straight portion 203b of each of the heat pipes 203 of the present exemplary embodiment is approximately equal to a length of the first straight portion 203a.

The connecting portion 203c of each of the heat pipes 203 extends from one end of the first straight portion 203a toward one end of the second straight portion 203b so as to protrude from the second principal surface 201b of the vapor chamber 201 and connects with one end of the second straight portion 203b. That is, the connecting portion 203c is made by folding back the second straight portion 203b so that the second straight portion 203b is approximately parallel to the first straight portion 203a. The connecting portion 203c of each of the heat pipes 203 has curved portions 203ca and 203cb formed in the vicinity of the first straight portion 203a and in the vicinity of the second straight portion 203b in order to prevent the connecting portion 203c from buckling (FIG. 3).

The heat radiation fin 205 is a member having a rectangular plate shape and made of metal (e.g., metal such as copper, aluminum, iron, magnesium, or an alloy including the metal). As illustrated in FIG. 3, each of the heat radiation fins 205 of the present exemplary embodiment has the through hole 205a into which the second straight portion 203b of each of the heat pipes 203 is inserted. In the present exemplary embodiment, the second straight portions 203b of the respective heat pipes 203 are sequentially inserted into the thirty-seven heat radiation fins 205, and the heat radiation fins 205 are disposed in the X-axis direction at predetermined intervals. Further, the respective through holes 205a of the respective heat radiation fins 205 are mechanically and thermally joined, by welding or soldering, to the second straight portions 203b of the respective heat pipes 203. In addition, a “⊐”-shaped cutout portion 205b is formed at an end in the Z-axis direction of each of the heat radiation fins 205 of the present exemplary embodiment, and the cutout portions 205b are spaced apart from one another so that the respective heat radiation fins 205 are not in contact with the first straight portions 203a of the respective heat pipes 203 (i.e., so that a gap S is formed between each of the heat radiation fins 205 and the first straight portion 203a of each of the heat pipes 203) (FIG. 2). In addition, the heat radiation fin 205 of the present exemplary embodiment is disposed so as not to deviate from the space adjoining the second principal surface 201b of the vapor chamber 201 so that the heat radiation fins 205 do not interrupt one another when the light irradiation devices 10 are connected.

In this way, the heat radiation fin 205 of the present exemplary embodiment is joined to the second straight portion 203b of each of the heat pipes 203 but not joined to the first straight portion 203a of each of the heat pipes 203. In this way, because a so-called cantilevered structure is implemented by the configuration in which the multiple heat radiation fins 205 are supported only by the second straight portions 203b, shear stress is generated in the first straight portion 203a or the connecting portion 203c of each of the heat pipes 203. Therefore, in the present exemplary embodiment, both ends E in the Y-axis direction of the heat radiation fin 205 protrude in the Z-axis direction and are joined to an edge portion of the second principal surface 201b of the vapor chamber 201 (i.e., an outer portion of the heat pipe mounting region HW), thereby inhibiting the generation of the shear stress (FIG. 2). That is, each of the heat radiation fins 205 is not joined to the second principal surface 201b of the vapor chamber 201 in the heat pipe mounting region HW, but joined directly to the second principal surface 201b of the vapor chamber 201 outside the heat pipe mounting region HW, thereby increasing mechanical strength.

When the drive current flows in the respective LED elements 110 and the ultraviolet rays are emitted from the respective LED elements 110, a temperature is raised by self-heating of the LED elements 110. However, the heat generated by the respective LED elements 110 is quickly transferred (moved) to the first straight portions 203a of the respective heat pipes 203 through the substrate 105 and the vapor chamber 201. Further, when the heat is moved to the first straight portions 203a of the respective heat pipes 203, the working fluid in the respective heat pipes 203 is vaporized by absorbing the heat, and the vapor of the working fluid is moved through the cavities in the connecting portions 203c and the second straight portions 203b, such that the heat of the first straight portions 203a is moved to the second straight portions 203b. Further, the heat moved to the second straight portions 203b is further moved to the multiple heat radiation fins 205 joined to the second straight portions 203b and dissipated into the air from the respective heat radiation fins 205. When the heat is dissipated from the respective heat radiation fins 205, a temperature of the second straight portions 203b is lowered, such that the vapor of the working fluid in the second straight portions 203b returns to the liquid by being cooled and moved to the first straight portions 203a. Further, the working fluid moved to the first straight portions 203a is used to newly absorb heat transferred through the substrate 105 and the vapor chamber 201.

In this way, in the present exemplary embodiment, since the working fluid in the respective heat pipes 203 circulates between the first straight portions 203a and the second straight portions 203b, the heat generated by the respective LED elements 110 is quickly moved to the heat radiation fins 205 and efficiently dissipated into the air from the heat radiation fins 205. Therefore, the temperature of the LED elements 110 is not excessively raised, and a problem of a considerable deterioration in luminous efficiency does not occur.

Further, coolability of the heat dissipation device 200 depends on the amount of heat transport of the vapor chamber 201 and the heat pipes 203 and the amount of heat dissipation of the heat radiation fins 205. In addition, because irregularity of irradiation intensity occurs due to a temperature property when a temperature difference occurs between the respective LED elements 110 two-dimensionally disposed on the substrate 105, the substrate 105 needs to be uniformly cooled in the X-axis direction and the Y-axis direction at a point of view of the irradiation intensity. In the present exemplary embodiment, since the substrate 105 is disposed in the effective area VC of the vapor chamber 201, the substrate 105 is uniformly cooled in the X-axis direction and the Y-axis direction.

In this way, according to the configuration of the present exemplary embodiment, the irregularity of coolability is low in the Y-axis direction and the X-axis direction, the substrate 105 may be regularly (approximately uniformly) cooled, and the 240 LED elements 110 disposed on the substrate 105 are also approximately uniformly cooled. Therefore, the temperature difference between the respective LED elements 110 is small, and the irregularity of the irradiation intensity caused by the temperature property is low. In addition, as illustrated in FIGS. 1 to 3, the heat pipes 203 and the heat radiation fins 205 of the present exemplary embodiment are configured not to deviate from the space adjoining the second principal surface 201b of the vapor chamber 201, such that the heat pipes 203 and the heat radiation fins 205 do not interrupt one another even when the light irradiation devices 10 are connected.

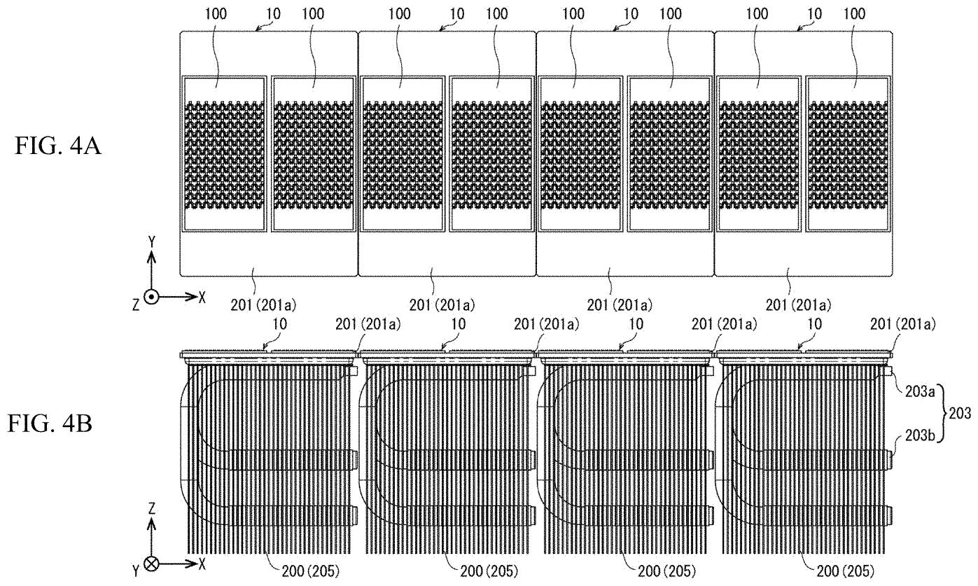

FIG. 4 is a view illustrating a state in which the light irradiation devices 10 of the present exemplary embodiment are connected in the X-axis direction, in which FIG. 4A is a front view (when viewed from a downstream side in the Z-axis direction (a side in a positive direction)), and FIG. 4B is a bottom view (when viewed from an upstream side in the Y-axis direction (a side in a negative direction)). As illustrated in FIG. 4B, since the light irradiation device 10 of the present exemplary embodiment is configured such that the heat pipes 203 and the heat radiation fins 205 do not deviate from the space adjoining the second principal surface 201b of the vapor chamber 201, the light irradiation devices 10 may be connected and disposed by joining the vapor chambers 201 in the X-axis direction so that the first principal surfaces 201a of the vapor chambers 201 are continuous. Therefore, it is possible to form linear irradiation areas having various sizes in accordance with the specifications and purposes.

(Simulation of Light Irradiation Device 10 and the Like)

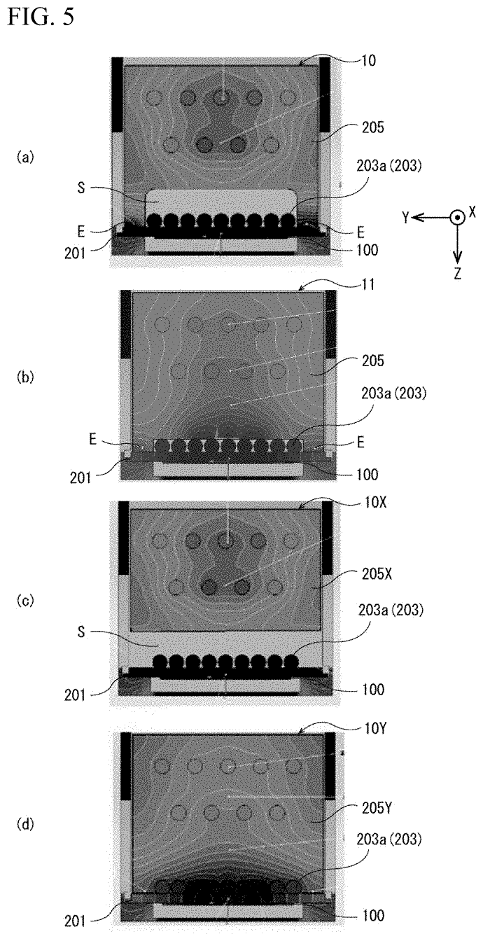

FIG. 5 is a view for explaining coolability of the light irradiation device 10 having the heat dissipation device 200 of the present exemplary embodiment and illustrates levels (distributions) of temperatures of the respective constituent elements (the LED unit 100, the heat pipes 203, the heat radiation fins 205, and the like) in accordance with light and shade of gray. FIG. 5A illustrates a simulation result of the light irradiation device 10 of the present exemplary embodiment, and FIG. 5B illustrates a simulation result of a light irradiation device 11 according to a modified example of the present exemplary embodiment. In addition, FIGS. 5B and 5C are simulation results of light irradiation devices 10X and 10Y according to comparative examples.

(Modified Example)

The light irradiation device 11 in FIG. 5B differs from the present exemplary embodiment in that the respective heat radiation fins 205 are partially joined to the first straight portions 203a of the respective heat pipes 203 (i.e., there is no gap S) in the heat pipe mounting region HW. More specifically, in the light irradiation device 11, each of the heat radiation fins 205 is joined to a portion corresponding to 10% of a circumference of the first straight portion 203a of each of the heat pipes 203. With this configuration, because each of the heat radiation fins 205 is fixed not only by the edge portion of the second principal surface 201b of the vapor chamber 201 (i.e., the outside of the heat pipe mounting region HW), but also in the heat pipe mounting region HW, the mechanical strength is further increased in comparison with the mechanical strength of the light irradiation device 10 of the present exemplary embodiment.

(Comparative Example)

The light irradiation device 10X in FIG. 5C differs from the present exemplary embodiment in that each heat radiation fin 205X does not have both ends E. The light irradiation device 10Y in FIG. 5D differs from the present exemplary embodiment in that each heat radiation fin 205Y is joined to the first straight portion 203a of each of the heat pipes 203 (i.e., the heat radiation fin 205Y is completely joined to the first straight portion 203a of each of the heat pipes 203 and the vapor chamber 201 in the heat pipe mounting region HW).

As can be seen from the comparison between FIGS. 5A and 5C, in the present exemplary embodiment (FIG. 5A), the heat is also transferred to both ends E of the heat radiation fin 205 from the edge portion of the second principal surface 201b of the vapor chamber 201. However, it can be seen that because a temperature distribution of the light irradiation device 10 and a temperature distribution of the light irradiation device 10X are approximately equal to each other, a difference between the two configurations (i.e., the presence and absence of both ends E of the heat radiation fin 205) rarely affects the coolability. That is, the configuration of the present exemplary embodiment maintains the equivalent coolability while having higher mechanical strength than the configuration in FIG. 5C.

As illustrated in FIG. 5D, when the heat radiation fin 205Y is completely joined to the first straight portion 203a of each of the heat pipes 203 and the vapor chamber 201 in the heat pipe mounting region HW, stress is hardly concentrated on the first straight portion 203a or the connecting portion 203c of each of the heat pipes 203, such that the mechanical strength may be further increased. However, as can be seen from the comparison between FIGS. 5A and 5D, it can be seen that because the heat is transferred directly to the heat radiation fin 205Y from the vapor chamber 201 in the heat pipe mounting region HW, the amount of heat transferred from the vapor chamber 201 to the first straight portion 203a is decreased, and the temperature of the first straight portion 203a is lowered in comparison with the configuration in FIG. 5A. That is, it can be seen that the heat transport by the respective heat pipes 203 is not properly performed, and as a result, the substrate 105 is not uniformly cooled (i.e., there occurs a temperature difference between the LED elements 110). Therefore, it can be understood that the configuration of the present exemplary embodiment illustrated in FIG. 5A is better than the configuration in FIG. 5D in that the mechanical strength of the respective heat pipes 203 is high and the substrate 105 may be uniformly cooled.

As can be seen from the comparison between FIGS. 5B and 5C, in the modified example (FIG. 5B), the heat is transferred from the edge portion of the second principal surface 201b of the vapor chamber 201 to both ends E of the heat radiation fin 205, and the heat is also transferred from the first straight portion 203a of the heat pipe 203 to the heat radiation fin 205. However, it can be seen that because the temperature of the first straight portion 203a of the light irradiation device 11 and the temperature of the first straight portion 203a of the light irradiation device 10X are approximately equal to each other, the difference between the two configurations (i.e., the presence or absence of the gap S) rarely affects the coolability. Meanwhile, when comparing FIGS. 5B and 5D, a sufficiently high temperature of the first straight portion 203a is maintained in the light irradiation device 11 (modified example), but a temperature of the first straight portion 203a of the light irradiation device 10Y (comparative example) is decreased. Therefore, it can be seen that in the state in which each of the heat radiation fins 205 is partially joined to the first straight portion 203a of each of the heat pipes 203 like in the light irradiation device 11 (modified example), heat resistance between each of the heat radiation fins 205 and the first straight portion 203a is sufficiently high and the function of the first straight portion 203a is not damaged. That is, it can be understood that the configuration of the modified example illustrated in FIG. 5B is better than the configurations in FIGS. 5C and 5D in that the mechanical strength of the respective heat pipes 203 may be increased and the substrate 105 may be uniformly cooled.

While the present exemplary embodiment has been described above, the present disclosure is not limited to the above-mentioned configurations, and various modifications may be made within the scope of the technical spirit of the present disclosure.

For example, the heat dissipation device 200 of the present exemplary embodiment is configured to have the 11 heat pipes 203 and the 60 heat radiation fins 205, but the number of heat pipes 203 and the number of heat radiation fins 205 are not limited. The number of heat radiation fins 205 is determined based on a relationship with the amount of heat generated by the LED elements 110, a temperature of air at a circumference of the heat radiation fins 205, or the like and appropriately selected in accordance with a so-called fin area where it is possible to dissipate the heat generated by the LED elements 110. In addition, the number of heat pipes 203 is determined based on a relationship with the amount of heat generated by the LED elements 110, the amount of heat transport of the respective heat pipes 203, or the like and appropriately selected so that the heat generated by the LED elements 110 may be sufficiently transported.

In addition, the configuration in which the heat dissipation device 200 of the present exemplary embodiment is naturally air-cooled has been described, but a fan for supplying cooling air is further provided in the heat dissipation device 200 in order to forcibly air-cool the heat dissipation device 200.

In addition, the configuration in which the heat dissipation device 200 of the present exemplary embodiment has the vapor chamber 201 has been described, but the present disclosure is not necessarily limited to this configuration, a rectangular plate-shaped member made of metal (e.g., copper, aluminum) having high thermal conductivity may be used instead of the vapor chamber 201 in accordance with the amount of heat generated by the LED elements 110.

In addition, in the present exemplary embodiment, both ends E of the heat radiation fin 205 protrude in the Z-axis direction and are joined to the edge portion of the second principal surface 201b of the vapor chamber 201, but the heat radiation fin 205 need not be necessarily joined to the edge portion of the second principal surface 201b as long as the heat radiation fin 205 is fixed to the vapor chamber 201.

Further, the exemplary embodiments disclosed herein are illustrative in all aspects and do not limit the present disclosure. The scope of the present disclosure is defined by the claims instead of the above-mentioned descriptions, and all modifications within the equivalent scope and meanings to the claims belong to the scope of the present disclosure.

1. A heat dissipation device disposed to be in close contact with a heat source and configured to dissipate heat of the heat source into the air, the heat dissipation device comprising:
a support member having a plate shape and disposed such that a side of a first principal surface is in close contact with the heat source;
a heat pipe thermally joined to a second principal surface opposite to the first principal surface of the support member and configured to transport the heat from the heat source; and
multiple heat radiation fins disposed in a space adjoining the second principal surface, thermally joined to the heat pipe, and configured to dissipate the heat transported by the heat pipe,
wherein the heat pipe has a first straight portion thermally joined to the support member, a second straight portion thermally joined to the multiple heat radiation fins, and a connecting portion connecting one end of the first straight portion and one end of the second straight portion so that the first straight portion and the second straight portion are connected, and
wherein the respective heat radiation fins are directly joined to the second principal surface in a region other than a region in which the heat pipe is mounted.

2. The heat dissipation device of claim 1, wherein the support member is a vapor chamber thermally joined to the heat source.

3. The heat dissipation device of claim 1, wherein each of the heat radiation fins is directly joined to the second principal surface at an edge portion of the second principal surface in a direction approximately orthogonal to a direction in which the first straight portion extends.

4. The heat dissipation device of claim 1, wherein each of the heat radiation fins is partially joined to the first straight portion in a region in which the heat pipe is mounted.

5. The heat dissipation device of claim 3, wherein each of the heat radiation fins is partially joined to the first straight portion in a region in which the heat pipe is mounted.

6. The heat dissipation device of claim 1, wherein the multiple heat pipes are provided, and the first straight portions of the respective heat pipes are disposed at predetermined intervals in a direction approximately orthogonal to a direction in which the first straight portion extends.

7. The heat dissipation device of claim 6, wherein when viewed in the direction in which the first straight portion extends, positions of the second straight portions of the respective heat pipes are different in a direction approximately perpendicular to the second principal surface and a direction approximately parallel to the second principal surface.

8. The heat dissipation device of claim 1, wherein when the multiple heat dissipation devices are arranged in the direction in which the first straight portion extends, the heat dissipation devices are connectable so that the first principal surfaces are continuous.

9. A light irradiation device comprising:
the heat dissipation device;
a substrate disposed to be in close contact with the heat dissipation device; and
multiple LED elements disposed on a surface of the substrate,
wherein the heat dissipation device comprises,
a support member having a plate shape and disposed such that a side of a first principal surface is in close contact with the substrate;
a heat pipe thermally joined to a second principal surface opposite to the first principal surface of the support member and configured to transport the heat from the substrate or the multiple LED elements; and
multiple heat radiation fins disposed in a space adjoining the second principal surface, thermally joined to the heat pipe, and configured to dissipate the heat transported by the heat pipe,
wherein the heat pipe has a first straight portion thermally joined to the support member, a second straight portion thermally joined to the multiple heat radiation fins, and a connecting portion connecting one end of the first straight portion and one end of the second straight portion so that the first straight portion and the second straight portion are connected, and
wherein the respective heat radiation fins are directly joined to the second principal surface in a region other than a region in which the heat pipe is mounted.

10. The light irradiation device of claim 9, wherein the LED element emits light with a wavelength that acts on ultraviolet curable resin.

11. The light irradiation device of claim 9, wherein the support member is a vapor chamber thermally joined to the heat source.

12. The light irradiation device of claim 9, wherein each of the heat radiation fins is directly joined to the second principal surface at an edge portion of the second principal surface in a direction approximately orthogonal to a direction in which the first straight portion extends.

13. The light irradiation device of claim 9, wherein each of the heat radiation fins is partially joined to the first straight portion in a region in which the heat pipe is mounted.

14. The light irradiation device of claim 12, wherein each of the heat radiation fins is partially joined to the first straight portion in a region in which the heat pipe is mounted.

15. The light irradiation device of claim 9, wherein the multiple heat pipes are provided, and the first straight portions of the respective heat pipes are disposed at predetermined intervals in a direction approximately orthogonal to a direction in which the first straight portion extends.

16. The light irradiation device of claim 15, wherein when viewed in the direction in which the first straight portion extends, positions of the second straight portions of the respective heat pipes are different in a direction approximately perpendicular to the second principal surface and a direction approximately parallel to the second principal surface.

17. The light irradiation device of claim 9, wherein when the multiple heat dissipation devices are arranged in the direction in which the first straight portion extends, the heat dissipation devices are connectable so that the first principal surfaces are continuous.
